(19) United States
(12) Patent Application Publication
(10) Pub. No.: US 2023/0155268 A1
(43) Pub. Date: May 18, 2023

(54) IMPEDANCE MATCHING FILM AND RADIO WAVE ABSORBER

(71) Applicant: NITTO DENKO CORPORATION, Ibaraki-shi, Osaka (JP)

(72) Inventors: Hirokazu Tanaka, Osaka (JP); Yosuke Nakanishi, Osaka (JP); Sho Shibahara, Osaka (JP); Hironobu Machinaga, Osaka (JP)

(73) Assignee: NITTO DENKO CORPORATION, Ibaraki-shi, Osaka (JP)

(21) Appl. No.: 17/914,962

(22) PCT Filed: Mar. 5, 2021
(86) PCT No.: PCT/JP2021/008820

§ 371 Date: Sep. 27, 2022

(30) Foreign Application Priority Data
Mar. 30, 2020 (JP) 2020-061580

(51) Int. Cl. H01P 1/24; H01Q 17/00; H01Q 15/14

(52) U.S. Cl. CPC H01P 1/24; H01Q 17/00; H01Q 15/14

(57) ABSTRACT

An impedance matching film 10a has a plurality of openings 11. The plurality of openings 11 are formed at equal intervals in a specific direction along main surfaces 10f of the impedance matching film 10a. The impedance matching film 10a has a sheet resistance of 300 to 700Ω/□. A size G of each opening 11 in the specific direction is 50 μm or more and 1000 μm or less. In the impedance matching film 10a, a cross-sectional resistance value Rₛ is 1MΩ/m or more. The cross-sectional resistance value Rₛ is determined by dividing a specific resistance of a material forming the impedance matching film 10a by a product of a thickness of the impedance matching film 10a and a distance between the nearest openings 11.

### TECHNICAL FIELD

The present invention relates to an impedance matching film and a radio wave absorber.

### BACKGROUND ART

Conventionally, the technology of matching the impedance of the surface of a radio wave absorber to the characteristic impedance of air by using a predetermined film has been known. Meanwhile, hitherto, there have been attempts to provide transparent radio wave absorbers.

For example, Patent Literature 1 describes a radio wave absorber in which all of component layers are transparent or translucent. In this radio wave absorber, a full-surface conductor layer, a first dielectric layer, a linear pattern resistive layer, a second dielectric layer, and a pattern layer are stacked in this order. According to this radio wave absorber, the pattern layer which is the outermost layer can satisfactorily receive electromagnetic waves. Since the pattern layer and the second dielectric layer are in contact with each other, leakage of the electromagnetic waves received by the pattern layer, to the second dielectric layer, is large. Since the second dielectric layer and the linear pattern layer are in contact with each other, the linear pattern layer can efficiently convert the electromagnetic waves that have leaked to the second dielectric layer, into heat.

Patent Literature 2 describes a visible light transmissive electromagnetic wave absorbing film. The visible light transmissive electromagnetic wave absorbing film has a plastic film and a visible light transmissive metal thin film. A large number of visible light transmissive metal thin films are arranged on at least one surface of the plastic film in a state where the visible light transmissive metal thin films are insulated from each other.

A large number of substantially parallel and linear marks are irregularly formed at intervals in at least one direction of each metal thin film. The electric resistance of each metal thin film in at least one side direction is 377±250Ω. The visible light transmissive electromagnetic wave absorbing film can sufficiently absorb electromagnetic wave noise having various frequencies. For example, according to EXAMPLES, the absorption ability for electromagnetic waves of 1 to 6 GHz is evaluated.

Patent Literature 3 describes an electromagnetic wave absorber having transparency. In the electromagnetic wave absorber, a reflective layer composed of a thin-line mesh pattern is formed on one surface of a transparent substrate. A transparent solid dielectric layer lies along the reflective layer with an adhesive agent layer interposed therebetween. Furthermore, a frequency selective shielding layer lies along the solid dielectric layer with an adhesive agent layer interposed therebetween.

The frequency selective shielding layer is composed of a thin-line pattern of an FSS element formed on one surface of a transparent substrate. A transparent solid dielectric layer lies along the frequency selective shielding layer with an adhesive agent layer interposed therebetween. A frequency selective shielding layer lies along the solid dielectric layer with an adhesive agent layer interposed therebetween. The frequency selective shielding layer is composed of a thin-line pattern of an FSS element formed on one surface of a transparent substrate. The thin-line mesh pattern of the reflective layer and the thin-line pattern of each frequency selective shielding layer have a line width of 15 to 80 μm.

### CITATION LIST

### Patent Literature

Patent Literature 1: JP 2006-179671 A
Patent Literature 2: JP 2010-283154 A
Patent Literature 3: JP 2009-170887 A

### SUMMARY OF INVENTION

### Technical Problem

It is thought that impedance matching films having transparency will be required for sensing using high-frequency radio waves such as millimeter waves. In addition, it is thought that impedance matching films having transparency will be required for a wide range of technological fields such as 5th generation mobile communication systems (5G) and the Internet of Things (IoT).

In order to provide an impedance matching film that can handle high-frequency radio waves and has transparency, it is conceivable to form a plurality of openings at equal intervals in an impedance matching film. In this case, diffraction and interference of light may cause an iridescent pattern on the impedance matching film. It is difficult to say that this is advantageous in terms of the appearance of the impedance matching film. In the technologies described in Patent Literatures 1 to 3, occurrence of such an iridescent pattern is not considered. Meanwhile, in a radio wave absorber including an impedance matching film having a plurality of openings formed at equal intervals therein, the absorption peak frequency of the radio wave absorber may deviate due to a phase shift in the impedance matching film.

In view of such circumstances, the present invention provides an impedance matching film that can handle high-frequency radio waves, has transparency, is less likely to cause an iridescent pattern, and is advantageous in terms of reducing deviation of the absorption peak frequency of a radio wave absorber.

### Solution to Problem

The present invention provides an impedance matching film, wherein the impedance matching film has a plurality of openings formed at equal intervals in a specific direction along a main surface of the impedance matching film, the impedance matching film has a sheet resistance of 300 to 700 Ω/□, a size of each opening in the specific direction is 50 μm or more and 1000 μm or less, and a cross-sectional resistance value determined by dividing a specific resistance of a material forming the impedance matching film by a product of a thickness of the impedance matching film and a distance between the nearest openings is 1 MΩ/m or more.

In addition, the present invention provides a radio wave absorber including:

the above impedance matching film;

a reflector for reflecting radio waves; and

a dielectric layer disposed between the impedance matching film and the reflector in a thickness direction of the impedance matching film.

### Advantageous Effects of Invention

The above impedance matching film can handle high-frequency radio waves and has transparency. In addition, an iridescent pattern is less likely to occur in the above impedance matching film, and the above impedance matching film is advantageous in terms of reducing deviation of the absorption peak frequency of a radio wave absorber.

### BRIEF DESCRIPTION OF THE DRAWINGS

FIG. 1A is a plan view showing an example of an impedance matching film according to the present invention.

FIG. 1B is a cross-sectional view of the impedance matching film taken along a line IB-IB in FIG. 1A.

FIG. 2A is a plan view showing another example of the impedance matching film according to the present invention.

FIG. 2B is a plan view showing still another example of the impedance matching film according to the present invention.

FIG. 2C is a plan view showing still another example of the impedance matching film according to the present invention.

FIG. 3A is a cross-sectional view showing an example of a radio wave absorber according to the present invention.

FIG. 3B is a cross-sectional view showing a modification of the radio wave absorber according to the present invention.

FIG. 3C is a cross-sectional view showing another modification of the radio wave absorber according to the present invention.

FIG. 4 is a cross-sectional view showing another example of the radio wave absorber according to the present invention.

### DESCRIPTION OF EMBODIMENTS

If an impedance matching film has a plurality of openings, this is advantageous in terms of imparting transparency to the impedance matching film. In addition, in order to suppress spatial variations in the transparency and impedance matching of the impedance matching film, it is advantageous to form the plurality of openings at equal intervals along a main surface of the impedance matching film. For example, if such an impedance matching film can handle high-frequency radio waves, the value of the impedance matching film can be further enhanced. Therefore, the present inventors have studied intensively on an impedance matching film that can handle high-frequency radio waves and has a plurality of openings. In the course of this study, the present inventors have noticed that an iridescent pattern occurs in the impedance matching film due to diffraction and interference of light. The present inventors have further studied and found that it is advantageous to increase the sizes of the openings in order to suppress occurrence of an iridescent pattern in the impedance matching film. Meanwhile, the present inventors have noticed that, if the sizes of the openings are increased in the impedance matching film, deviation of the absorption peak frequency of a radio wave absorber tends to be larger. Therefore, the present inventors have conducted a great deal of trial and error, have finally found a condition that can achieve both suppression of occurrence of an iridescent pattern in the impedance matching film and reduction of deviation of the absorption peak frequency of a radio wave absorber, and have conceived of an impedance matching film according to the present invention. As used herein, “transparency” means transparency to visible light, unless otherwise described.

Embodiments of the present invention will be described with reference to the drawings. The present invention is not limited to the following embodiments.

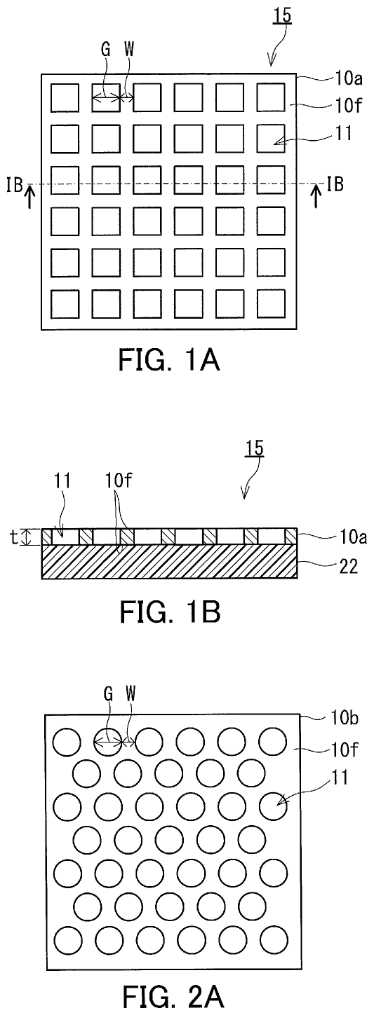

As shown in FIG. 1A and FIG. 1B, an impedance matching film 10a has a plurality of openings 11. The plurality of openings 11 are formed at equal intervals in a specific direction along main surfaces 10f of the impedance matching film 10a. As used herein, the main surfaces 10f mean a front surface and a back surface located apart from each other in the thickness direction of the impedance matching film 10a. Each of the plurality of openings 11 is typically formed as a through hole in the impedance matching film 10a. The impedance matching film 10a has a sheet resistance of 300 to 700 Ω/□. Accordingly, impedance matching for high-frequency radio waves is easily performed. A size G of each opening 11 in the specific direction is 50 μm or more and 1000 μm or less. Accordingly, occurrence of an iridescent pattern is suppressed on the impedance matching film 10a, and deviation of the absorption peak frequency of a radio wave absorber is easily reduced. A cross-sectional resistance value Rₛ of the impedance matching film 10a is 1 MΩ/m or more. Accordingly, deviation of the absorption peak frequency of a radio wave absorber including the impedance matching film 10a is easily reduced. The cross-sectional resistance value Rₛ is determined by dividing a specific resistance p of the material forming the impedance matching film 10a by the product (tW) of a thickness t of the impedance matching film 10a and a distance W between the nearest openings 11.

The specific resistance p of the material forming the impedance matching film 10a can be determined on the basis of a relationship of Rf=(ρ/t){(G+W)/W}, for example, by taking a fragment having a predetermined dimension from the impedance matching film 10a and measuring a sheet resistance Rf of the fragment, the size G of the opening 11, the distance W between the nearest openings 11, and the thickness t. The sheet resistance Rf can be measured according to the eddy current method using a non-contact resistance meter. The size G of the opening 11 and the distance W between the nearest openings 11 can be determined by observing the fragment using an optical microscope. In addition, the thickness t of the impedance matching film 10a can be determined, for example, by observing a cross-section of the impedance matching film 10a using a transmission electron microscope (TEM). Moreover, the specific resistance p of the material forming the impedance matching film 10a may be determined by analyzing the material composition of the material, forming a film having the same composition as the material composition, and measuring the sheet resistance and the thickness of the film.

The impedance matching film 10a desirably has a sheet resistance of 350 Ω/□ or more. In this case, better impedance matching for high-frequency radio waves is easily performed by the impedance matching film 10a. The sheet resistance of the impedance matching film 10a can be measured, for example, according to the eddy current method.

The size G of each opening 11 in the specific direction is desirably 100 μm or more, more desirably 150 μm or more, and further desirably 200 μm or more, and may be 250 μm or more, or may be 300 μm or more. The size G of each opening 11 may be 950 μm or less, may be 900 μm or less, or may be 850 μm or less.

The cross-sectional resistance value Rₛ is, for example, 20 MΩ/m or less, and may be 18 MΩ/m or less, may be 16 MΩ/m or less, may be 14 MΩ/m or less, may be 12 MΩ/m or less, may be 10 MΩ/m or less, may be 8 MΩ/m or less, may be 5 MΩ/m or less, or may be 3 MΩ/m or less.

The thickness t of the impedance matching film 10a is not limited to a specific value as long as the impedance matching film 10a has a sheet resistance of 300 to 700 Ω/□ and the cross-sectional resistance value thereof is 1 MΩ/m or more. The thickness t is, for example, 5 nm or more. In this case, the sheet resistance of the impedance matching film 10a is less likely to vary over a long period of time, and the impedance matching film 10a easily exhibits high durability.

The thickness t of the impedance matching film 10a may be 10 nm or more or may be 15 nm or more. The thickness t is, for example, 500 nm or less. Accordingly, warpage of the impedance matching film 10a is easily suppressed, so that cracks are less likely to occur in the impedance matching film 10a. The thickness t may be 450 nm or less or may be 400 nm or less.

The value of the distance W between the nearest openings 11 is not limited to a specific value as long as the impedance matching film 10a has a sheet resistance of 300 to 700 Ω/□ and the cross-sectional resistance value thereof is 1 MΩ/m or more. The value of the distance W may be, for example, 100 μm or less. On the other hand, the value of the distance W is desirably 10 μm or less. Accordingly, in the impedance matching film 10a, a frame that is in contact with the openings 11 is less likely to be visually recognized when the impedance matching film 10a is viewed in a plan view.

An opening ratio in the impedance matching film 10a is not limited to a specific value as long as the size G of each opening 11 in the specific direction is 50 μm or more and 1000 μm or less, the impedance matching film 10a has a sheet resistance of 300 to 700 Ω/□, and the cross-sectional resistance value thereof is 1 MΩ/m or more. The opening ratio in the impedance matching film 10a may be, for example, 40% or more. On the other hand, the opening ratio in the impedance matching film 10a is desirably 65% or more. Accordingly, the impedance matching film 10a easily has high transparency. The opening ratio of the plurality of openings 11 is a ratio Sa/(Sa+Sb) of an opening area Sa of the plurality of openings 11 to a sum Sa+Sb of the opening area Sa of the plurality of openings 11 and an area Sb of the non-opening portion of the impedance matching film 10a when the impedance matching film 10a is viewed in a plan view.

The opening ratio in the impedance matching film 10a is more desirably 70% or more and further desirably 75% or more. The opening ratio in the impedance matching film 10a is, for example, 99% or less, and may be 98% or less, or may be 97% or less.

The specific resistance p of the material forming the impedance matching film 10a is not limited to a specific value as long as the impedance matching film 10a has a sheet resistance of 300 to 700 Ω/□ and the cross-sectional resistance value Rₛ thereof is 1 MΩ/m or more. The specific resistance ρ is, for example, 4×10⁻⁵ to 1×10⁻⁴ Ω·cm. Accordingly, deviation of the absorption peak frequency of the radio wave absorber including the impedance matching film 10a is easily reduced more reliably. The specific resistance p is desirably 5×10⁻⁵ to 1×10⁻⁴ Ω·cm.

The arrangement of the plurality of openings 11 is not limited to a specific arrangement as long as the plurality of openings 11 are formed at equal intervals in the specific direction along the main surfaces 10f. For example, the specific direction may include a plurality of alignment directions intersecting each other. For example, in the impedance matching film 10a, the plurality of openings 11 are arranged such that the centers thereof form a square lattice on the main surfaces 10f. In other words, in the impedance matching film 10a, the specific direction includes alignment directions orthogonal to each other.

The shapes of the plurality of openings 11 are not limited to specific shapes. For example, in the impedance matching film 10a, the plurality of openings 11 each have a square shape in a plan view.

The material forming the impedance matching film 10a is not limited to a specific material as long as the impedance matching film 10a has a sheet resistance of 300 to 700 Ω/□ and the cross-sectional resistance value thereof is 1 MΩ/m or more. The material forming the impedance matching film 10a may be an inorganic material such as metals, alloys, and metal oxides, or may be an organic material such as electroconductive polymers and carbon nanotubes.

The impedance matching film 10a may be a film having a plurality of through holes formed therein and having a uniform thickness, or may be a woven fabric. The fiber forming the woven fabric may be an organic material such as electroconductive polymers and carbon nanotubes, or may be an inorganic material such as metals and alloys.

As shown in FIG. 1B, the impedance matching film 10a may be formed, for example, on one main surface of a substrate 22. In this case, the impedance matching film 10a can be provided by an impedance matching film-attached film 15. The impedance matching film 10a may be provided alone without using the substrate 22.

The substrate 22 serves, for example, as a support for supporting the impedance matching film 10a. The impedance matching film 10a in the impedance matching film-attached film 15 can be produced, for example, by forming the plurality of openings 11 by laser processing, etching, or the like in a non-porous film formed on one main surface of the substrate 22 by a film forming method such as sputtering. In some cases, a non-porous film for the impedance matching film 10a may be formed by a film forming method such as ion plating or coating (for example, bar coating).

The substrate 22 has, for example, a thickness of 10 to 150 μm, and desirably has a thickness of 15 to 100 μm. Accordingly, the flexural rigidity of the substrate 22 is low, and it is possible to suppress wrinkling or deformation of the substrate 22 when forming the impedance matching film 10a.

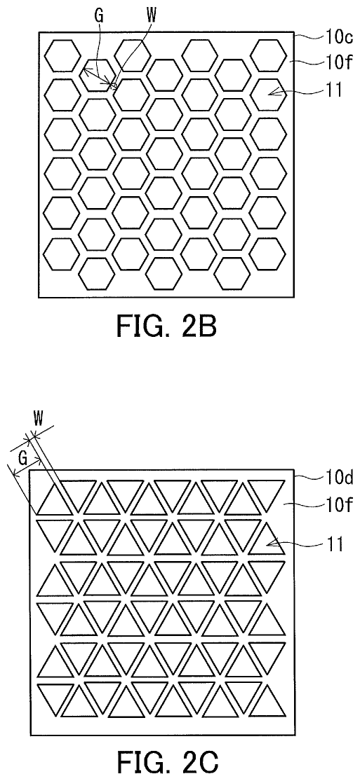

As for the arrangement and the shapes of the plurality of openings 11, the impedance matching film 10a may be modified into an impedance matching film 10b shown in FIG. 2A, an impedance matching film 10c shown in FIG. 2B, or an impedance matching film 10d shown in FIG. 2C. Each of the impedance matching film 10b, the impedance matching film 10c, and the impedance matching film 10d is configured in the same manner as the impedance matching film 10a, except for the portions that are particularly described. The components, of the impedance matching film 10b, the impedance matching film 10c, and the impedance matching film 10d, identical to or corresponding to the components of the impedance matching film 10a are indicated by the same reference characters, and the detailed descriptions thereof are omitted. The descriptions given for the impedance matching film 10a are also applicable to the impedance matching film 10b, the impedance matching film 10c, and the impedance matching film 10d unless there is a technical inconsistency.

As shown in FIG. 2A, in the impedance matching film 10b, the plurality of openings 11 each have a circular shape in a plan view. In addition, the plurality of openings 11 are arranged such that the centers thereof form a parallelogram lattice on the main surfaces 10f. The plurality of openings 11 may be arranged so as to form a square lattice.

As shown in FIG. 2B, in the impedance matching film 10c, the plurality of openings 11 each have a regular hexagonal shape in a plan view. In addition, the plurality of openings 11 are arranged such that the centers thereof form a parallelogram lattice on the main surfaces 10f.

As shown in FIG. 2C, in the impedance matching film 10d, the plurality of openings 11 each have an equilateral triangle shape in a plan view. In addition, a plurality of the openings 11 having equilateral triangle shapes having the same orientation are arranged such that the centers thereof form a parallelogram lattice on the main surfaces 10f. Herein, the center of gravity of a planar figure is regarded as the center of an opening having a planar figure shape.

The plurality of openings 11 may each have another polygonal shape such as a rectangular shape, or an elliptical shape, in a plan view. The plurality of openings 11 may be arranged such that the centers thereof form another planar lattice such as a rectangular lattice on the main surfaces 10f. As used herein, the planar lattice means an array of points on a plane that are unchanged as a result of parallel shift for a constant distance in each of two independent directions.

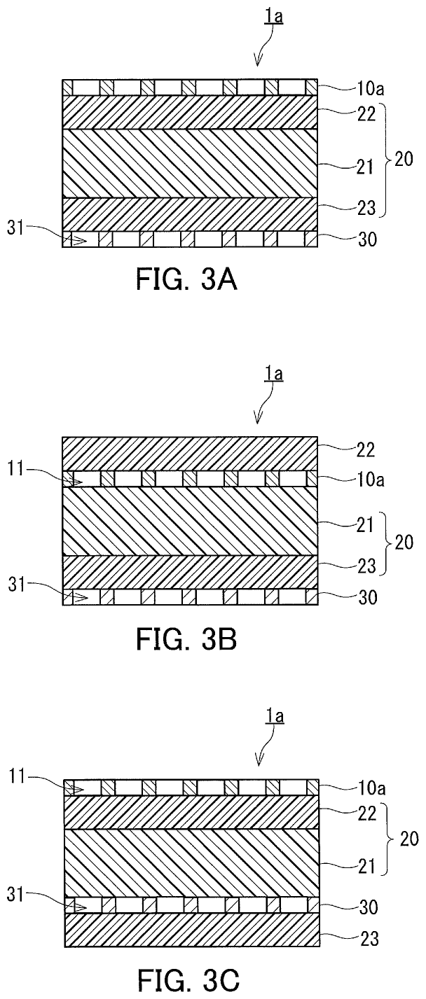

As shown in FIG. 3A, a radio wave absorber 1a can be provided, for example, using the impedance matching film 10a. The radio wave absorber 1a includes the impedance matching film 10a, a reflector 30 for reflecting radio waves, and a dielectric layer 20. The dielectric layer 20 is disposed between the impedance matching film 10a and the reflector 30 in the thickness direction of the impedance matching film 10a.

The radio wave absorber 1a is, for example, a λ/4 radio wave absorber. The radio wave absorber 1a is designed such that, when radio waves of a wavelength λₒ to be absorbed by the radio wave absorber 1a are incident on the radio wave absorber 1a, radio waves resulting from reflection on the front surface of the impedance matching film 10a (front surface reflection) and radio waves resulting from reflection on the reflector 30 (back surface reflection) interfere with each other. In the λ/4 radio wave absorber, as shown in the following equation (1), the wavelength λₒ of the radio waves to be absorbed is determined according to a thickness t of the dielectric layer and a relative permittivity Er of the dielectric layer. That is, the radio waves of the wavelength to be absorbed can be set by adjusting the relative permittivity and the thickness of the dielectric layer as appropriate. In the equation (1), sqrt(εᵣ) means the square root of the relative permittivity εᵣ.

λₒ=4t×sqrt(εᵣ) Equation (1)

The radio wave absorber 1a is configured to be able to absorb radio waves in a predetermined frequency range of 20 GHz or more, for example. Examples of the frequency ranges of radio waves that can be absorbed by the radio wave absorber 1a are as follows. The following radio waves are under consideration for use as radio waves for 5G in various countries.

27.5 to 29.5 GHz

27.5 to 28.35 GHz

24.25 to 24.45 GHz

24.75 to 25.25 GHz

37 to 38.6 GHz

38.6 to 40 GHz

47.2 to 48.2 GHz

64 to 71 GHz

24.25 to 27.5 GHz

40.5 to 43.5 GHz

66 to 71 GHz

24.75 to 27.5 GHz

37 to 42.5 GHz

27.5 to 29.5 GHz

31.8 to 33.4 GHz

37 to 40.5 GHz

Other examples of the frequency ranges of the radio waves that can be absorbed by the radio wave absorber 1a are as follows. The following radio waves can be used as radio waves for a millimeter wave radar.

21.65 to 26.65 GHz

60 to 61 GHz

76 to 77 GHz

77 to 81 GHz

94.7 to 95 GHz

139 to 140 GHz

The radio wave absorber 1a has, for example, an absorption peak frequency of 20 GHz or more. This allows absorption of desired high-frequency radio waves.

An absorption peak frequency fp is the frequency of a radio wave whose return loss ISI is the maximum for the radio wave absorber 1a. The return loss ISI is the absolute value of S calculated by the following equation (2). In the equation (2), Po is the power of transmitted radio waves when radio waves are incident on a measurement target at a predetermined incident angle, and Pᵢ is the power of received radio waves in this case. The value of the return loss ISI for the radio wave absorber 1a is determined, for example, with the value of the return loss ISI when radio waves are incident on a plate of a reference metal such as aluminum at a predetermined incident angle being regarded as 0 dB. In the radio wave absorber 1a, front surface reflection of radio waves having the absorption peak frequency fp occurs properly, and the radio wave absorber 1a can satisfactorily absorb the radio waves having the absorption peak frequency fp.

S[dB]=10×log|Pᵢ/Pₒ| Equation (2)

The radio wave absorber 1a exhibits, for example, a return loss of 10 dB or more, and desirably exhibits a return loss of 20 dB or more, in a predetermined frequency range of 20 GHz or more.

The reflector 30 is not limited to a specific form as long as the radio waves to be absorbed can be reflected. The reflector 30 is, for example, a transparent conductive film. In this case, the reflector 30 has transparency, and the entire radio wave absorber 1a is easily made transparent. The material forming the transparent conductive film may be an inorganic material such as metals including aluminum, etc., alloys, and metal oxides, or may be an organic material such as electroconductive polymers and carbon nanotubes. The reflector 30 may be an opaque conductive film. The material forming such a conductive film may be an inorganic material such as metals including aluminum, etc., alloys, and metal oxides, or may be an organic material such as electroconductive polymers and carbon nanotubes.

The transparent conductive film has, for example, a plurality of openings 31 formed regularly along main surfaces of the transparent conductive film. This configuration allows the reflector 30 to properly reflect radio waves to be absorbed and makes it easier for the reflector 30 to have desired transparency. The transparent conductive film may be a non-porous film.

In the case where the reflector 30 has the plurality of openings 31, the impedance matching film 10a may be a film having a plurality of through holes formed therein and having a uniform thickness, or may be a woven fabric. The fiber forming the woven fabric may be an organic material such as electroconductive polymers and carbon nanotubes, or may be an inorganic material such as metals and alloys.

The shapes of the plurality of openings 31 in the reflector 30 are not limited to specific shapes. Each of the shapes of the plurality of openings 31 may be, for example, a triangular shape, a quadrilateral shape such as a square shape and a rectangular shape, a hexagonal shape, another polygonal shape, a circular shape, or an elliptical shape in a plan view.

The arrangement of the plurality of openings 31 in the reflector 30 is not limited to a specific arrangement. The plurality of openings 31 may be arranged such that, for example, the centers of the plurality of openings 31 form a planar lattice such as a square lattice and a parallelogram lattice.

The dielectric layer 20 has, for example, a relative permittivity of 2.0 to 20.0. In this case, it is easy to adjust the thickness of the dielectric layer 20, and it is easy to adjust the radio wave absorption performance of the radio wave absorber 1a. The relative permittivity of the dielectric layer 20 is, for example, a relative permittivity at 10 GHz measured according to the cavity resonance method.

The dielectric layer 20 is formed, for example, from a predetermined polymer. The dielectric layer 20 contains, for example, at least one polymer selected from the group consisting of ethylene-vinyl acetate copolymer, vinyl chloride resin, urethane resin, acrylic resin, acrylic urethane resin, acrylic-based elastomer, polyethylene, polypropylene, silicone, polyethylene terephthalate, polyethylene naphthalate, polycarbonate, polyimide, and cycloolefin polymer. In this case, it is easy to adjust the thickness of the dielectric layer 20, and the production cost of the radio wave absorber 1a can be kept low. The dielectric layer 20 can be produced, for example, by hot-pressing a predetermined resin composition.

The dielectric layer 20 may be formed as a single layer, or may be formed of a plurality of layers made of the same material or different materials. In the case where the dielectric layer 20 has n layers (n is an integer equal to or greater than 2), the relative permittivity of the dielectric layer 20 is determined as follows, for example. A relative permittivity εᵢ of each layer is measured (i is an integer from 1 to n). Next, εᵢ×(tᵢ/T) is obtained by multiplying the measured relative permittivity εᵢ of each layer by the ratio of a thickness t₁ of the layer to a total thickness T of the dielectric layer 20. The relative permittivity of the dielectric layer 20 can be determined by adding up εᵢ×(tᵢ/T) of all the layers.

As shown in FIG. 3A, the dielectric layer 20 includes, for example, a first layer 21, a second layer 22, and a third layer 23. The first layer 21 is disposed between the second layer 22 and the third layer 23. The first layer 21 contains, for example, at least one polymer selected from the group consisting of ethylene-vinyl acetate copolymer, vinyl chloride resin, urethane resin, acrylic resin, acrylic urethane resin, polyethylene, polypropylene, silicone, polyethylene terephthalate, polyethylene naphthalate, polycarbonate, polyimide, and cycloolefin polymer.

In the radio wave absorber 1a, the second layer 22 serves as a substrate for the impedance matching film 10a. The second layer 22 is disposed, for example, at a position closer to the reflector 30 than the impedance matching film 10a is. As shown in FIG. 3B, the second layer 22 may be disposed at a position farther from the reflector 30 than the impedance matching film 10a is. In this case, the dielectric layer 20 is composed of the first layer 21 and the third layer 23. In this case, the impedance matching film 10a and the dielectric layer 20 are protected by the second layer 22, and the radio wave absorber 1a has high durability. In this case, for example, the impedance matching film 10a may be in contact with the first layer 21. The material of the second layer 22 is, for example, polyethylene terephthalate (PET), polyethylene naphthalate (PEN), acrylic resin (PMMA), polycarbonate (PC), polyimide (PI), or cycloolefin polymer (COP). Among them, the material of the second layer 22 is desirably PET in terms of the balance among good heat resistance, dimensional stability, and manufacturing cost.

In the radio wave absorber 1a, the third layer 23 supports the reflector 30, for example. In this case, the reflector 30 may be produced, for example, by forming a film on the third layer 23 using a method such as sputtering, ion plating, or coating (for example, bar coating). Furthermore, the plurality of openings 31 may be formed by laser processing, etching, or the like. As shown in FIG. 3A, the third layer 23 is disposed, for example, at a position closer to the impedance matching film 10a in the radio wave absorber 1a than the reflector 30 is, and forms a part of the dielectric layer 20. As shown in FIG. 3C, the third layer 23 may be disposed at a position farther from the impedance matching film 10a than the reflector 30 is. In this case, for example, the reflector 30 is in contact with the first layer 21.

As the material of the third layer 23, for example, the materials exemplified as the material of the second layer 22 can be used. The material of the third layer 23 may be the same as or different from the material of the second layer 22. The material of the third layer 23 is desirably PET in terms of the balance among good heat resistance, dimensional stability, and manufacturing cost.

The third layer 23 has, for example, a thickness of 10 to 150 μm, and desirably has a thickness of 15 to 100 μm. Accordingly, the flexural rigidity of the third layer 23 is low, and it is possible to suppress wrinkling or deformation of the third layer 23 when forming the reflector 30. The third layer 23 may be omitted in some cases.

The first layer 21 may be composed of a plurality of layers. In particular, in the case where the first layer 21 is in contact with at least one of the impedance matching film 10a and the reflector 30 as shown in FIG. 3B or FIG. 3C, the first layer 21 can be composed of a plurality of layers.

The first layer 21 may have adhesiveness, or may not necessarily have adhesiveness. In the case where the first layer 21 has adhesiveness, an adhesive layer may be disposed in contact with at least one of both main surfaces of the first layer 21, or adhesive layers may not necessarily be disposed in contact with both main surfaces of the first layer 21, respectively. In the case where the first layer 21 does not have adhesiveness, adhesive layers are desirably disposed in contact with both main surfaces of the first layer 21, respectively. In the case where the dielectric layer 20 includes the second layer 22, even if the second layer 22 does not have adhesiveness, adhesive layers may not necessarily be disposed in contact with both main surfaces of the second layer 22, respectively. In this case, an adhesive layer can be disposed in contact with one main surface of the second layer 22. In the case where the dielectric layer 20 includes the third layer 23, even if the third layer 23 does not have adhesiveness, adhesive layers may not necessarily be disposed in contact with both main surfaces of the third layer 23, respectively. In this case, an adhesive layer can be disposed in contact with at least one main surface of the third layer 23. Each adhesive layer contains, for example, a rubber-based adhesive agent, an acrylic-based adhesive agent, a silicone-based adhesive agent, or a urethane-based adhesive agent. The thickness of each adhesive layer containing the adhesive agent is not limited to a specific value, and is, for example, 3 to 50 μm, and desirably 5 to 30 μm.

The radio wave absorber 1a may contain at least one of a dielectric loss material and a magnetic loss material. In other words, the radio wave absorber 1a may be a dielectric loss radio wave absorber or a magnetic loss radio wave absorber. The dielectric layer 20 may contain at least one of a dielectric loss material and a magnetic loss material. The material forming the impedance matching film 10a may be magnetic.

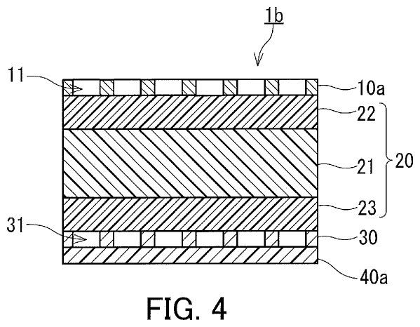

The radio wave absorber 1a can be modified in various respects. For example, the radio wave absorber 1a may be modified into a radio wave absorber 1b shown in FIG. 4. The radio wave absorber 1b is configured in the same manner as the radio wave absorber 1a except for the portions that are particularly described. The components, of the radio wave absorber 1b, identical to or corresponding to the components of the radio wave absorber 1a are indicated by the same reference characters, and the detailed descriptions thereof are omitted. The descriptions given for the radio wave absorber 1a are also applicable to the radio wave absorber 1b unless there is a technical inconsistency.

As shown in FIG. 4, the radio wave absorber 1b further includes an adhesive layer 40a. In the radio wave absorber 1b, the reflector 30 is disposed between the dielectric layer 20 and the adhesive layer 40a.

For example, the radio wave absorber 1b can be adhered to a predetermined article by pressing the radio wave absorber 1b against the article with the adhesive layer 40a brought into contact with the article. Accordingly, a radio wave absorber-attached article can be obtained.

The adhesive layer 40a contains, for example, a rubber-based adhesive agent, an acrylic-based adhesive agent, a silicone-based adhesive agent, or a urethane-based adhesive agent. The radio wave absorber 1b may further include a release liner(not shown). In this case, the release liner covers the adhesive layer 40a. The separator is typically a film that can maintain the adhesive strength of the adhesive layer 40a when covering the adhesive layer 40a and that can easily be peeled from the adhesive layer 40a. The release liner is, for example, a film made of polyester resin such as PET. By peeling the release liner, the adhesive layer 40a becomes exposed, allowing the radio wave absorber 1b to be adhered to an article.

### EXAMPLES

Hereinafter, the present invention will be described in more detail by means of Examples. The present invention is not limited to the following Examples. First, evaluation methods for the Examples and Comparative Examples will be described.

[Tem Observation]

Cross-sectional observation samples of a non-porous film according to each of the Examples and the Comparative Examples and an alloy film in an alloy film-attached film according to each of the Examples and the Comparative Examples were prepared using a focused ion beam processing observation apparatus (product name: FB-2000A, manufactured by Hitachi High-Tech Corporation). Then, the cross-sectional observation samples were observed using a field emission transmission electron microscope (product name: HF-2000, manufactured by Hitachi High-Tech Corporation), and the thickness of the non-porous film according to each of the Examples and the Comparative Examples was measured. The thickness of the non-porous film was regarded as the thickness of the alloy film in the alloy film-attached film according to each of the Examples and the Comparative Examples. The results are shown in Table 1.

[Specific Resistance, Sheet Resistance, and Cross-Sectional Resistance Value]

The sheet resistance of the alloy film in the alloy film-attached film according to each of the Examples and the Comparative Examples was measured by the eddy current method according to JIS Z 2316 using a non-contact type resistance measurement device NC-80LINE manufactured by NAPSON CORPORATION. Meanwhile, the sheet resistance of the non-porous film according to each of the Examples and the Comparative Examples was measured in the same manner. The product of the thickness of the non-porous film measured as described above and the sheet resistance of the non-porous film measured as described above was obtained to determine the specific resistance of the material forming the non-porous film. The specific resistance of the material forming the non-porous film was regarded as the specific resistance of the material forming the alloy film in the alloy film-attached film according to each of the Examples and the Comparative Examples. In each of the Examples and the Comparative Examples, a cross-sectional resistance value Rₛ was determined by dividing the specific resistance of the material forming the alloy film, by the product of the thickness of the alloy film and the distance between the nearest openings in the alloy film-attached film. The results are shown in Table 1.

[Appearance Check]

In a state where the alloy film-attached film of the sample according to each of the Examples and the Comparative Examples was irradiated with light from a white light source, whether or not an iridescent pattern was observed was checked. When an iridescent pattern was not observed, the film was evaluated as “A”, and when an iridescent pattern was observed, the film was evaluated as “X”. In addition, whether or not an alloy frame of the alloy film-attached film of each sample can be visually recognized was visually checked. When the alloy frame was not recognized, the film was evaluated as “A”, and when the alloy frame was recognized, the film was evaluated as “X”. The results are shown in Table 1.

[Radio Wave Absorption Performance]

With reference to JIS R 1679: 2007, radio waves having frequencies of 60 to 90 GHz were made incident at an incident angle of 0° on the sample according to each of the Examples and the Comparative Examples fixed to a sample holder, using a vector network analyzer manufactured by ANRITSU CORPORATION, and a return loss ISI at each frequency was determined according to the above equation (2). Instead of the sample according to each of the Examples and the Comparative Examples, an aluminum plate was fixed to the sample holder, a return loss ISI when radio waves were incident perpendicularly on the plate was regarded as 0 dB, and the return loss ISI of each sample was determined. The plate had a face dimension of 30 cm square, and the thickness of the plate was 5 mm. For each sample, the maximum value of the return loss ISI and the frequency (absorption peak frequency fp) at which the maximum value was exhibited were determined. When the maximum value of the return loss ISI is 10 dB or more, the sample can be evaluated to have good radio wave absorption performance. In addition, a shift amount [%] from 77 GHz which is the frequency of radio waves to be absorbed having the absorption peak frequency in each sample was determined according to the following equation (3). The results are shown in Table 1.

Shift amount[%]=100×(fp−77)/77 Equation (3)

### Example 1

DC magnetron sputtering was performed using an Al (aluminum) target material and an Si (silicon) target material and using argon gas as a process gas, to form an Al—Si alloy film on a PET film. In the DC magnetron sputtering, discharge involving the Al (aluminum) target material and discharge involving the Si (silicon) target material were performed simultaneously. Thus, a non-porous film according to Example 1 was formed on the PET film. The specific resistance of the material forming the non-porous film according to Example 1 was 4.8×10⁻⁵ Ω·cm. The non-porous film had a thickness of 30 nm. Next, using a metal laser patterning machine, a plurality of square-shaped openings were formed at equal intervals in the non-porous film according to Example 1 so as to form a square lattice, to obtain an alloy film-attached film according to Example 1. In a plan view of the alloy film-attached film according to Example 1, the size of each opening in the direction in which the plurality of openings were arranged at equal intervals was 220 μm, and the distance between the nearest openings was 10 μm. The alloy film in the alloy film-attached film can function as an impedance matching film.

DC magnetron sputtering was performed using an ITO target material containing 10 weight % of SnO₂ and using argon and oxygen as process gases, to form an ITO film on a PET film. Then, the ITO film was annealed under the condition of a temperature of 150° C. for 1 hour to polycrystallize the ITO, to obtain a reflector-attached film. The sheet resistance of the reflector of the reflector-attached film was 20 Ω/□. Next, an acrylic resin having a relative permittivity of 2.6 was molded so as to have a thickness of 560 μm, to obtain an acrylic resin layer A. The alloy film-attached film according to Example 1 was put on the acrylic resin layer A such that the alloy film of the alloy film-attached film according to Example 1 was in contact with the acrylic resin layer A. Next, the reflector-attached film was put on the acrylic resin layer A such that the ITO in the reflector-attached film was in contact with the acrylic resin layer A. Thus, a sample according to Example 1 was obtained.

### Example 2

A non-porous film according to Example 2 was formed on a PET film and an alloy film-attached film according to Example 2 was obtained, in the same manner as Example 1 except for the following. In DC magnetron sputtering, the ratio of the discharge power of the discharge involving the Si (silicon) target material to the discharge power of the discharge involving the Al (aluminum) target material was adjusted such that the specific resistance of the material forming the non-porous film according to Example 2 was 5.0×10⁻⁵ Ω·cm. In addition, the conditions of the DC magnetron sputtering were adjusted such that the thickness of the alloy film in the alloy film-attached film according to Example 2 was 50 nm. Next, using a metal laser patterning machine, a plurality of square-shaped openings were formed at equal intervals in the non-porous film according to Example 2 so as to form a square lattice, to obtain an alloy film-attached film according to Example 2. In a plan view of the alloy film-attached film according to Example 2, the size of each opening in the direction in which the plurality of openings were arranged at equal intervals was 600 μm, and the distance between the nearest openings was 10 μm.

A sample according to Example 2 was obtained in the same manner as Example 1, except that the alloy film-attached film according to Example 2 was used instead of the alloy film-attached film according to Example 1.

### Example 3

A non-porous film according to Example 3 was formed on a PET film and an alloy film-attached film according to Example 3 was obtained, in the same manner as Example 1 except for the following. In DC magnetron sputtering, the ratio of the discharge power of the discharge involving the Si (silicon) target material to the discharge power of the discharge involving the Al (aluminum) target material was adjusted such that the specific resistance of the material forming the non-porous film according to Example 3 was 1.0×10⁻⁴ Ω·cm. In addition, the conditions of the DC magnetron sputtering were adjusted such that the thickness of the alloy film in the alloy film-attached film according to Example 3 was 5 nm. Next, using a metal laser patterning machine, a plurality of square-shaped openings were formed at equal intervals in the non-porous film according to Example 3 so as to form a square lattice, to obtain an alloy film-attached film according to Example 3. In a plan view of the alloy film-attached film according to Example 3, the size of each opening in the direction in which the plurality of openings were arranged at equal intervals was 50 μm, and the distance between the nearest openings was 10 μm.

A sample according to Example 3 was obtained in the same manner as Example 1, except that the alloy film-attached film according to Example 3 was used instead of the alloy film-attached film according to Example 1.

### Example 4

A non-porous film according to Example 4 was formed on a PET film and an alloy film-attached film according to Example 4 was obtained, in the same manner as Example 1 except for the following. In DC magnetron sputtering, the ratio of the discharge power of the discharge involving the Si (silicon) target material to the discharge power of the discharge involving the Al (aluminum) target material was adjusted such that the specific resistance of the material forming the non-porous film according to Example 4 was 5.0×10⁻⁵ Ω·cm. In addition, the conditions of the DC magnetron sputtering were adjusted such that the thickness of the alloy film in the alloy film-attached film according to Example 4 was 5 nm. Next, using a metal laser patterning machine, a plurality of square-shaped openings were formed at equal intervals in the non-porous film according to Example 4 so as to form a square lattice, to obtain an alloy film-attached film according to Example 4. In a plan view of the alloy film-attached film according to Example 4, the size of each opening in the direction in which the plurality of openings were arranged at equal intervals was 200 μm, and the distance between the nearest openings was 100 μm

A sample according to Example 4 was obtained in the same manner as Example 1, except that the alloy film-attached film according to Example 4 was used instead of the alloy film-attached film according to Example 1.

### Comparative Example 1

A non-porous film according to Comparative Example 1 was formed on a PET film and an alloy film-attached film according to Comparative Example 1 was obtained, in the same manner as Example 1 except for the following. In DC magnetron sputtering, the ratio of the discharge power of the discharge involving the Si (silicon) target material to the discharge power of the discharge involving the Al (aluminum) target material was adjusted such that the specific resistance of the material forming the non-porous film according to Comparative Example 1 was 1.0×10⁻⁴ Ω·cm. In addition, the conditions of the DC magnetron sputtering were adjusted such that the thickness of the alloy film in the alloy film-attached film according to Comparative Example 1 was 5 nm. Next, using a metal laser patterning machine, a plurality of square-shaped openings were formed at equal intervals in the non-porous film according to Comparative Example 1 so as to form a square lattice, to obtain an alloy film-attached film according to Comparative Example 1. In a plan view of the alloy film-attached film according to Comparative Example 1, the size of each opening in the direction in which the plurality of openings were arranged at equal intervals was 20 μm, and the distance between the nearest openings was 10 μm.

A sample according to Comparative Example 1 was obtained in the same manner as Example 1, except that the alloy film-attached film according to Comparative Example 1 was used instead of the alloy film-attached film according to Example 1.

### Comparative Example 2

A non-porous film according to Comparative Example 2 was formed on a PET film and an alloy film-attached film according to Comparative Example 2 was obtained, in the same manner as Example 1 except for the following. In DC magnetron sputtering, the ratio of the discharge power of the discharge involving the Si (silicon) target material to the discharge power of the discharge involving the Al (aluminum) target material was adjusted such that the specific resistance of the material forming the non-porous film according to Comparative Example 2 was 5×10⁻⁵ Ω·cm. In addition, the conditions of the DC magnetron sputtering were adjusted such that the thickness of the alloy film in the alloy film-attached film according to Comparative Example 2 was 50 nm. Next, using a metal laser patterning machine, a plurality of square-shaped openings were formed at equal intervals in the non-porous film according to Comparative Example 2 so as to form a square lattice, to obtain an alloy film-attached film according to Comparative Example 2. In a plan view of the alloy film-attached film according to Comparative Example 2, the size of each opening in the direction in which the plurality of openings were arranged at equal intervals was 1500 μm, and the distance between the nearest openings was 50 μm

A sample according to Comparative Example 2 was obtained in the same manner as Example 1, except that the alloy film-attached film according to Comparative Example 2 was used instead of the alloy film-attached film according to Example 1.

### Comparative Example 3

A non-porous film according to Comparative Example 3 was formed on a PET film and an alloy film-attached film according to Comparative Example 3 was obtained, in the same manner as Example 1 except for the following. In DC magnetron sputtering, the ratio of the discharge power of the discharge involving the Si (silicon) target material to the discharge power of the discharge involving the Al (aluminum) target material was adjusted such that the specific resistance of the material forming the non-porous film according to Comparative Example 3 was 5.0×10⁻⁵ Ω·cm. In addition, the conditions of the DC magnetron sputtering were adjusted such that the thickness of the alloy film in the alloy film-attached film according to Comparative Example 3 was 50 nm. Next, using a metal laser patterning machine, a plurality of square-shaped openings were formed at equal intervals in the non-porous film according to Comparative Example 3 so as to form a square lattice, to obtain an alloy film-attached film according to Comparative Example 3. In a plan view of the alloy film-attached film according to Comparative Example 3, the size of each opening in the direction in which the plurality of openings were arranged at equal intervals was 1000 μm, and the distance between the nearest openings was 50 μm

A sample according to Comparative Example 3 was obtained in the same manner as Example 1, except that the alloy film-attached film according to Comparative Example 3 was used instead of the alloy film-attached film according to Example 1.

### Comparative Example 4

A non-porous film according to Comparative Example 4 was formed on a PET film and an alloy film-attached film according to Comparative Example 4 was obtained, in the same manner as Example 1 except for the following. In DC magnetron sputtering, the ratio of the discharge power of the discharge involving the Si (silicon) target material to the discharge power of the discharge involving the Al (aluminum) target material was adjusted such that the specific resistance of the material forming the non-porous film according to Comparative Example 4 was 5.0×10⁻⁵ Ω·cm. In addition, the conditions of the DC magnetron sputtering were adjusted such that the thickness of the alloy film in the alloy film-attached film according to Comparative Example 4 was 100 nm. Next, using a metal laser patterning machine, a plurality of square-shaped openings were formed at equal intervals in the non-porous film according to Comparative Example 4 so as to form a square lattice, to obtain an alloy film-attached film according to Comparative Example 4. In a plan view of the alloy film-attached film according to Comparative Example 4, the size of each opening in the direction in which the plurality of openings were arranged at equal intervals was 800 μm, and the distance between the nearest openings was 5 μm.

A sample according to Comparative Example 4 was obtained in the same manner as Example 1, except that the alloy film-attached film according to Comparative Example 4 was used instead of the alloy film-attached film according to Example 1.

### Comparative Example 5

A non-porous film according to Comparative Example 5 was formed on a PET film and an alloy film-attached film according to Comparative Example 5 was obtained, in the same manner as Example 1 except for the following. In DC magnetron sputtering, the ratio of the discharge power of the discharge involving the Si (silicon) target material to the discharge power of the discharge involving the Al (aluminum) target material was adjusted such that the specific resistance of the material forming the non-porous film according to Comparative Example 5 was 5.0×10⁻⁵ Ω·cm. In addition, the conditions of the DC magnetron sputtering were adjusted such that the thickness of the alloy film in the alloy film-attached film according to Comparative Example 5 was 100 nm. Next, using a metal laser patterning machine, a plurality of square-shaped openings were formed at equal intervals in the non-porous film according to Comparative Example 5 so as to form a square lattice, to obtain an alloy film-attached film according to Comparative Example 5. In a plan view of the alloy film-attached film according to Comparative Example 5, the size of each opening in the direction in which the plurality of openings were arranged at equal intervals was 600 μm, and the distance between the nearest openings was 10 μm.

A sample according to Comparative Example 5 was obtained in the same manner as Example 1, except that the alloy film-attached film according to Comparative Example 5 was used instead of the alloy film-attached film according to Example 1.

As shown in Table 1, no iridescent pattern was observed in the sample according to each Example. On the other hand, in the sample according to Comparative Example 1, an iridescent pattern was observed. Therefore, it was suggested that each of the sizes of the openings formed at equal intervals being 50 μm or more in the impedance matching film is advantageous in terms of suppressing occurrence of an iridescent pattern. In the sample according to each Example, the shift amount was 10% or less. On the other hand, in each of the samples according to Comparative Examples 2, 3, and 5, the shift amount exceeded 10%. Therefore, it is suggested that the cross-sectional resistance value Rₛ being 1 MΩ/m or more in the impedance matching film is advantageous in reducing deviation of the absorption peak frequency. It is difficult to say that the samples according to Comparative Examples 2 and 4 had good radio wave absorption performance.

TABLE 1

| | Sheet | Specific resistance | | | | Distance |
|---|---|---|---|---|---|---|
| | resistance of | of material forming | Cross-sectional | Thickness of | Size of | between |
| | alloy film | alloy film | resistance value Rₛ | alloy film | opening | openings |
| | [Ω/□] | [Ω · cm] | [MΩ/m] | [nm] | [μm] | [μm] |
| Ex. 1 | 397 | 4.8 × 10⁻⁵ | 1.6 | 30 | 220 | 10 |
| Ex. 2 | 610 | 5.0 × 10⁻⁵ | 1.0 | 50 | 600 | 50 |
| Ex. 3 | 300 | 1.0 × 10⁻⁴ | 1.0 | 5 | 50 | 10 |
| Ex. 4 | 300 | 5.0 × 10⁻⁵ | 1.0 | 5 | 200 | 100 |
| Comp. Ex. 1 | 300 | 1.0 × 10⁻⁴ | 20 | 5 | 20 | 10 |
| Comp. Ex. 2 | 310 | 5.0 × 10⁻⁵ | 0.2 | 50 | 1500 | 50 |
| Comp. Ex. 3 | 210 | 5.0 × 10⁻⁵ | 0.2 | 50 | 1000 | 50 |
| Comp. Ex. 4 | 805 | 5.0 × 10⁻⁵ | 1.0 | 100 | 800 | 5 |
| Comp. Ex. 5 | 305 | 5.0 × 10⁻⁵ | 0.5 | 100 | 600 | 10 |

| | | Presence/absence | Visual | Absorption peak | | |
|---|---|---|---|---|---|---|
| | Opening ratio | of iridescent | recognition of | frequency fp | Shift amount | Return loss |
| | [%] | pattern | frame | [GHz] | [%] | [dB] |
| Ex. 1 | 91.5 | A | A | 74.2 | −3.6 | 36.5 |
| Ex. 2 | 96.7 | A | X | 81.8 | 6.2 | 25.8 |
| Ex. 3 | 69.4 | A | A | 78.7 | 2.2 | 13.9 |
| Ex. 4 | 44.4 | A | X | 80.6 | 4.7 | 23.1 |
| Comp. Ex. 1 | 44.4 | X | X | 77.4 | 0.52 | 18.5 |
| Comp. Ex. 2 | 93.7 | A | X | 84.8 | 10.1 | 5.0 |
| Comp. Ex. 3 | 90.7 | A | A | 90 or more | 16.8 or more | — |
| Comp. Ex. 4 | 98.8 | A | A | 81.5 | 5.8 | 6.9 |
| Comp. Ex. 5 | 96.7 | A | A | 90 or more | 16.8 or more | — |

1. An impedance matching film, wherein
the impedance matching film has a plurality of openings formed at equal intervals in a specific direction along a main surface of the impedance matching film,
the impedance matching film has a sheet resistance of 300 to 700 Ω/□,
a size of each opening in the specific direction is 50 μm or more and 1000 μm or less, and
a cross-sectional resistance value determined by dividing a specific resistance of a material forming the impedance matching film by a product of a thickness of the impedance matching film and a distance between the nearest openings is 1 MΩ/m or more.

2. The impedance matching film according to claim 1, wherein the impedance matching film has a thickness of 5 nm or more.

3. The impedance matching film according to claim 1, wherein the distance between the nearest openings is 10 μm or less.

4. The impedance matching film according to claim 1, wherein the impedance matching film has an opening ratio of 65% or more.

5. The impedance matching film according to claim 1, wherein the specific resistance is 4×10⁻⁵ to 1×10⁻⁴ Ω·cm.

6. A radio wave absorber comprising:
the impedance matching film according to claim 1;
a reflector for reflecting radio waves; and
a dielectric layer disposed between the impedance matching film and the reflector in a thickness direction of the impedance matching film.

7. The radio wave absorber according to claim 6, wherein the reflector is a transparent conductive film.

8. The radio wave absorber according to claim 6, wherein the radio wave absorber has an absorption peak frequency of 20 GHz or more.
